(19) United States
(12) Patent Application Publication
(10) Pub. No.: US 2019/0062902 A1
(43) Pub. Date: Feb. 28, 2019

(54) EVAPORATION SOURCE DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventors: Junying MU, Wuhan, Hubei (CN); Sangyeob LEE, Wuhan, Hubei (CN); Xianjie LI, Wuhan, Hubei (CN)

(21) Appl. No.: 15/575,615

(22) PCT Filed: Oct. 27, 2017
(86) PCT No.: PCT/CN2017/107998

§ 371 Date: Nov. 20, 2017

(30) Foreign Application Priority Data
Aug. 22, 2017 (CN) 201710722815.4

(51) Int. Cl. C23C 14/54; C23C 14/24

(52) U.S. Cl. CPC C23C 14/542; C23C 14/243

(57) ABSTRACT

An evaporation source device is provided and includes an evaporation source disposed below a substrate; an evaporation source shielding plate disposed between the evaporation source and the substrate; and a driving part connected with the evaporation source shielding plate. The driving part drives the evaporation source shielding plate to rotate with respect to the evaporation source, and controls a rotation speed of the evaporation source shielding plate during a coating process, to adjust an evaporation rate of the evaporation source.

### FIELD OF THE INVENTION

The present disclosure relates to a technical field of displays, and particularly to an evaporation source device.

### BACKGROUND OF THE INVENTION

Organic light emitting diode (OLED) display technology has advantages such as having a high contrast, a wide color gamut, being flexible, light, and thin, as well as energy saving, which are compared to current mainstream liquid crystal display technology. It has gradually become widely used in the field of mobile devices, such as smart phones and tablet computers, the field of flexible wearable devices such as smart watches, the field of the large size curved-televisions (TV), and the field of white lighting.

OLED technology mainly includes small molecule OLED technology based on a vacuum evaporation technology and polymer OLED technology based on a solution process. An evaporation machine is a main production equipment for small molecule OLED devices in mass production, and a core part thereof are evaporation source devices, wherein the evaporation sources are divided such as a point evaporation source, a line evaporation source, a surface evaporation source, etc. The line evaporation source is currently an important OLED technology in mass production, and is mainly divided into an integrated line evaporation source and a conveyor line evaporation source.

As shown in FIG. 1, the existing point evaporation source is widely used in research and development, and mass production equipment. In an evaporation chamber, evaporation sources 11 to 14 are distributed on the bottom of the chamber along a circular arc, one of restriction plates 16 is disposed between the adjacent evaporation sources to restrict a reaching range of evaporative airflow. In addition, a substrate 10 is positioned over the evaporation sources 11 to 14, and is rotated along a center of the substrate 10 and the chamber during the evaporation, so as to improve film thickness uniformity. A starting time and an ending time of a film coating on each of evaporation sources is controlled by independent evaporation source shielding plates 15. Rotation of each of the evaporation source shielding plates 15 is controlled by a cylinder, such that the existing evaporation sources only have states of on and off. Thus, it is difficult in the coating process to control a coating rate and a doping ratio.

Therefore, it is necessary to provide an evaporation source device to solve problems existing in the prior art.

### SUMMARY OF THE INVENTION

An object of the present disclosure is to provide an evaporation source device which is able to control a coating rate of the evaporation source during a coating process.

In order to resolve the above problem, an evaporation source device is provided according to the present disclosure, which is configured for evaporation of a substrate, and includes:

an evaporation source disposed below the substrate;
an evaporation source shielding plate disposed between the evaporation source and the substrate; and
a driving part connected with the evaporation source shielding plate, wherein the driving part is configured to drive the evaporation source shielding plate to rotate with respect to the evaporation source, and control a rotation speed of the evaporation source shielding plate during a coating process, to adjust an evaporation rate of the evaporation source; the driving part further configured to control a rotation cycle of the evaporation source shielding plate during the coating process, wherein the rotation cycle of the evaporation source shielding plate during the coating process is defined according to a rotation cycle of the substrate; wherein the evaporation source device further comprises an evaporation chamber, and wherein the evaporation source, the evaporation source shielding plate, and the substrate are all located in the evaporation chamber.

In the evaporation source device of the present disclosure, the driving part is configured to control the rotation speed of the evaporation source shielding plate during the coating process, such that a shielding area between the evaporation source shielding plate and the evaporation source is changed, to adjust the evaporation rate of the evaporation source.

In the evaporation source device of the present disclosure, operation states of the evaporation source device comprise a fully closed state, a partially open state, and a fully open state.

In the evaporation source device of the present disclosure, while the evaporation source device is in the fully closed state, the evaporation source shielding plate fully shields the evaporation source; while the evaporation source device is in the partially open state, the evaporation source shielding plate partially shields the evaporation source; and while the evaporation source device is in the fully open state, the evaporation source shielding plate does not shield the evaporation source.

The evaporation source device of the present disclosure further includes a driving shaft, wherein the evaporation source shielding plate is disposed on an upper end of the driving shaft, and a lower end of the driving shaft is connected with the driving part.

In the evaporation source device of the present disclosure, the rotation speed of the evaporation source shielding plate during the coating process is defined according to the rotation cycle of the substrate.

In the evaporation source device of the present disclosure, the evaporation source device comprises at least two of the evaporation sources and at least two of the evaporation source shielding plates, each of the evaporation sources is corresponding to one of the evaporation source shielding plates; and a restriction plate is disposed between two of the evaporation sources adjacent to each other, and configured to restrict a vapor deposition area of the evaporation source.

In the evaporation source device of the present disclosure, the driving part is further configured to control a doping ratio of a coating material in the at least two evaporation sources.

An evaporation source device is also provided in the present disclosure, which is configured for evaporation of a substrate, and includes:

an evaporation source disposed below the substrate;
an evaporation source shielding plate disposed between the evaporation source and the substrate; and
a driving part connected with the evaporation source shielding plate, wherein the driving part is configured to drive the evaporation source shielding plate to rotate with respect to the evaporation source, and control a rotation speed of the evaporation source shielding plate during a coating process, to adjust an evaporation rate of the evaporation source.

In the evaporation source device of the present disclosure, the driving part is configured to control the rotation speed of the evaporation source shielding plate during the coating process, such that a shielding area between the evaporation source shielding plate and the evaporation source is changed, to adjust the evaporation rate of the evaporation source.

In the evaporation source device of the present disclosure, operation states of the evaporation source device comprise a fully closed state, a partial open state, and a fully open state.

In the evaporation source device of the present disclosure, while the evaporation source device is in the fully closed state, the evaporation source shielding plate fully shields the evaporation source; while the evaporation source device is in the partially open state, the evaporation source shielding plate partially shields the evaporation source; and while the evaporation source device is in the fully open state, the evaporation source shielding plate does not shield the evaporation source.

The evaporation source device of the present disclosure further includes a driving shaft, wherein the evaporation source shielding plate is disposed on an upper end of the driving shaft, and a lower end of the driving shaft is connected with the driving part.

In the evaporation source device of the present disclosure, the rotation speed of the evaporation source shielding plate during the coating process is defined according to the rotation cycle of the substrate.

In the evaporation source device of the present disclosure, the driving part is further configured to control a rotation cycle of the evaporation source shielding plate during the coating process, wherein the rotation cycle of the evaporation source shielding plate during the coating process is defined according to a rotation cycle of the substrate.

In the evaporation source device of the present disclosure, the evaporation source device comprises at least two of the evaporation sources and at least two of the evaporation source shielding plates, each of the evaporation sources is corresponding to one of evaporation source shielding plates; and a restriction plate is disposed between two of the evaporation sources adjacent to each other, and configured to restrict a vapor deposition area of the evaporation source.

In the evaporation source device of the present disclosure, the driving part is further configured to control a doping ratio of a coating material in the at least two evaporation sources.

The evaporation source device of the present disclosure further includes an evaporation chamber, wherein all of the evaporation source, the evaporation source shielding plate, and the substrate are located in the evaporation chamber.

The evaporation source device of the present disclosure is achieved by improving a driving part in the prior art, the evaporation rate of the evaporation source is controlled by setting the rotation rate of the drive part during the coating process, so as to control the evaporation rate of the corresponding evaporation source. In addition, while two or more evaporation sources are co-evaporated, the doping ratio of the coating materials of the corresponding evaporation source can also be controlled.

### BRIEF DESCRIPTION OF THE DRAWINGS

FIG. 1 is a top view of an evaporation source device in prior art.

FIG. 2 is a schematic diagram of a structure of an evaporation source device of the present disclosure.

FIG. 3 is a first top view of positions of evaporation source shielding plates in the evaporation source device of the present disclosure.

FIG. 4 is a second top view of positions of evaporation source shielding plates in the evaporation source device of the present disclosure.

FIG. 5 is a graph showing a relationship between thicknesses and doping ratios for two coating materials in the evaporation source device of the present disclosure.

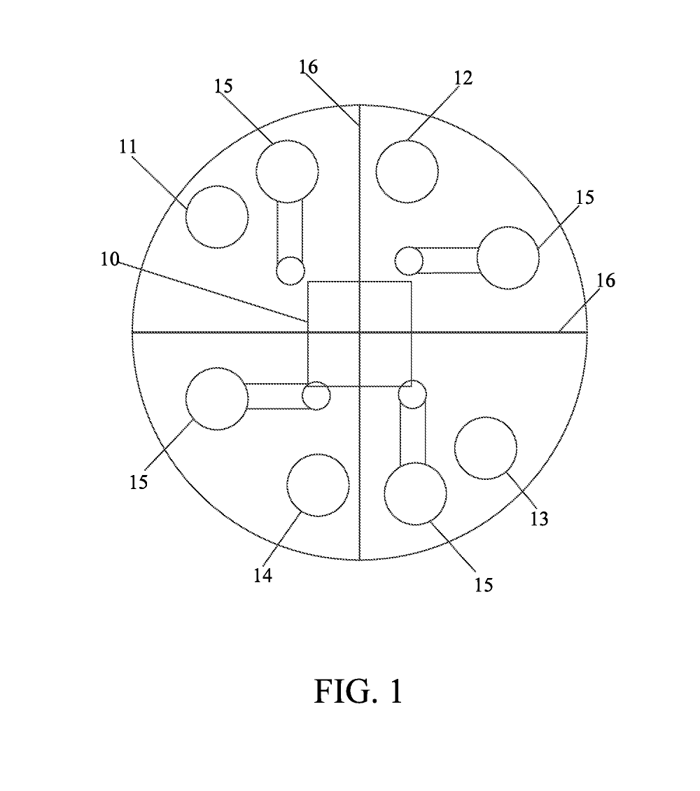

### DETAILED DESCRIPTION OF THE PREFERRED EMBODIMENTS

The following description of each embodiment refers to the appended drawings for illustrating specific embodiments in which the present disclosure may be practiced. Directional terms as mentioned in the present disclosure, such as “up”, “down”, “front”, “post”, “left”, “right”, “inside”, “outside”, “lateral”, etc., are merely used for the purpose of illustrating and understanding the present disclosure and are not intended to be limiting of the present disclosure. In the drawings, units with similar structures are denoted by the same reference numerals.

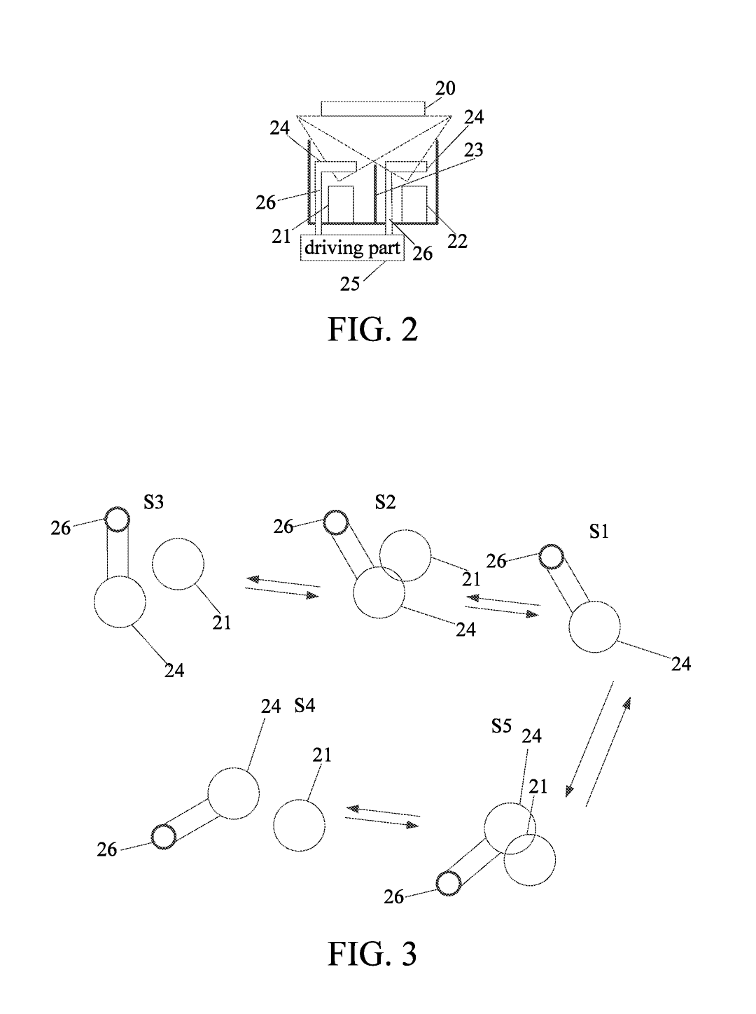

An evaporation source device of this embodiment is configured for evaporation of a substrate, as shown in FIG. 2, the evaporation source device includes two evaporation sources 21, 22, two evaporation source shielding plate 24, and a driving part 25, all of them are disposed in an evaporation chamber.

The evaporation sources 21, 22 are disposed below the substrate 20, respectively. One of the evaporation source shielding plates 24 is configured for one of the evaporation sources. The evaporation source shielding plate 24 provided for a left side is disposed between the evaporation sources 21 and the substrate 20, and the evaporation source shielding plate 24 provided for a right side is disposed between the evaporation sources 22 and the substrate 20, with a restriction plate 23 is disposed between the evaporation sources 21 and 22, and is provided in a vertical direction.

The restriction plate 23 serves to restrict an evaporation area of the evaporation sources 21 and 22. In addition, an evaporation range of the evaporated air stream is shown by the dotted line in the figure.

The driving part 25 is electrically connected to the evaporation source shielding plate 24. The driving part 24 is configured to drive the evaporation source shielding plate 24 to rotate with respect to a corresponding evaporation source, and is configured to control a rotation rate of the evaporation source shielding plate 24 during a coating process, to adjust an evaporation rate of each of the evaporation sources. In an embodiment, the driving part is a motor.

Wherein the evaporation source device further includes a driving shaft 26, the evaporation source shielding plate 24 is disposed on an upper end of the driving shaft 26, and a lower end of the driving shaft 26 is connected with the driving part 25. Wherein one end of the evaporation source shielding plate 24 is disposed at the upper end of the driving shaft 26. Specifically, the driving part 25 may drive the evaporation source shielding plate 24 to rotate with the driving shaft 26 as a rotating shaft.

Take the evaporation source shielding plate provided for the left side as an example, as shown in FIG. 3, the evaporation source shielding plate 24 may be a transition from a fully closed state S1 to a fully open state S3 at a constant rate (e.g., rotation at an average speed), with an intermediate experience of a partially open state S2, and then, the evaporation source shielding plate 24 may be a transition from a fully open state S4 to the fully closed state S1, with an intermediate experience of a partially open state S5, thereby completing an action cycle. It is understandable that an action cycle of the evaporation source shield provided for the right side is similar to the action cycle of the evaporation source shield provided for the left side.

That is, operation states of the evaporation source device include the fully closed state, the partially open state, and the fully open state.

While the evaporation source device is in the fully closed state, the evaporation source shielding plate 24 fully shields the evaporation source 21; while the evaporation source device is in the partially open state, the evaporation source shielding plate 24 partially shields the evaporation source 21; and while the evaporation source device is in the fully open state, the evaporation source shielding plate 24 does not shield the evaporation source 21.

The driving part 25 is specifically configured to change a shielding area between the evaporation source shielding plate 24 and the evaporation source 21 by controlling a rotation speed of the evaporation source shielding plate 24 during a coating process, to adjust an evaporation rate of the evaporation source. While the evaporation source device is in the fully closed state, the shielding area between the evaporation source shielding plate 24 and the evaporation source 21 is maximized, and the evaporation rate is the lowest rate. While the evaporation source device is in the partially open state, the shielding area between the evaporation source shielding plate 24 and the evaporation source 21 is between a maximum value and a minimum value, and the evaporation rate is at a middle value (i.e., between the highest rate and the lowest rate). While the evaporation source device is in the fully open state, the shielding area between the evaporation source shielding plate 24 and the evaporation source 21 is minimized, and the evaporation rate is the highest rate.

The rotation speed of the evaporation source shielding plate 24 during the coating process is defined according to the rotation cycle of the substrate 20.

The driving part 25 is further configured to control a rotation cycle of the evaporation source shielding plate 24 during the coating process, wherein the rotation cycle of the evaporation source shielding plate 24 during the coating process is defined according to a rotation cycle of the substrate 20.

Such as the rotation cycle of the substrate is 6 to 10 RPM (Rev/min), the rotation rate and cycle of the evaporation source shielding plate 24 may be defined according to the rotation rate and cycle of the substrate 20 during the coating process, to optimize a doping ratio and coating uniformity. In addition, the driving part 25 is further configured to control the doping ratio of a coating material in the two evaporation sources.

In an embodiment, the evaporation source shielding plate 24 is rotated at a set speed (e.g., a constant rotation) for an operation cycle (1 cycle) in a continuous rotation during the coating process. The substrate 20 rotates 360 degrees (°) as one revolution, which is worked in with a rotation speed of the substrate 20 (such as 10 RPM), then the rotation speed of the substrate 20 is 60 degrees/Sec.

According to this speed, the speed the evaporation source shielding plate 24 is defined as 360 degrees/8=45 degrees/cycle, namely, the rotation speed of the evaporation source shielding plate 24 is 45/60 Sec./cycle. Further, according to a simulation result, the rotation rate and cycle of the evaporation source shielding plate 24 are optimized, to optimize the doping ratio and coating uniformity.

While the substrate 20 is rotated within 0 to 45 degrees (i.e., the rotation angle between 0 to 45 degrees), the open and closed state of the evaporation source shielding plate 24 are show such as S1-S2-S3-S2-S1.

While the substrate 20 is rotated within 45 to 90 degrees, the open and closed state of the evaporation source shielding plate 24 are shown such as S1-S5-S4-S5-S1.

The mention as above is one cycle (0 to 90 degrees of rotation of the substrate), while four cycles are repeated, the substrate 20 completes a rotating operation in one revolution.

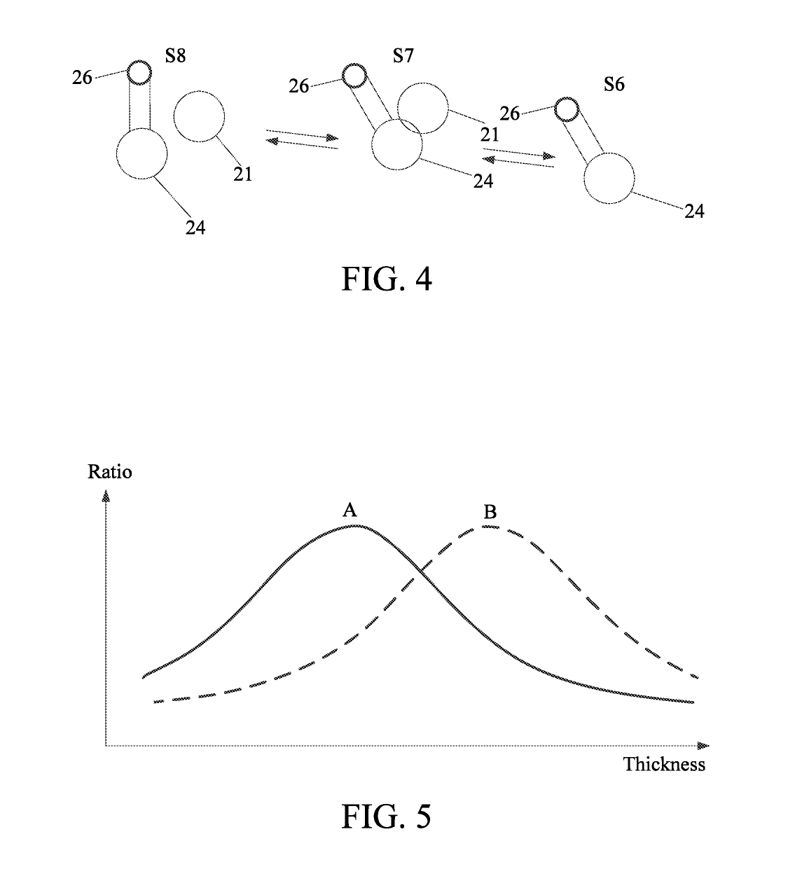

In another embodiment, the evaporation source shielding plate 24 is rotated at a set speed (e.g., the constant rotation) for an operation cycle (1 cycle) in a continuous rotation during the coating process, as shown in FIG. 4. The substrate 20 rotates 360 degrees as one revolution, which is worked in with a rotation speed of the substrate 20 (such as 10 RPM), then the rotation speed of the substrate 20 is 60 degrees/Sec.

While the substrate 20 is rotated within 0 to 30 degrees, the speed of the evaporation source shielding plate 24 is defined according to the speed of the substrate 20 such as 30 degrees/cycle, namely, the rotation speed of the evaporation source shielding plate 24 is 30/60 Sec./cycle. The open and closed state of the evaporation source shielding plate 24 are shown such as S8-S7-S6-S7-S8.

Then, while the substrate 20 is rotated to 60 degrees, the evaporation source shielding plate 24 maintains the open state.

The mention as above is one cycle, while four cycles are repeated, the substrate 20 completes a rotating operation in one revolution.

It is understandable that the evaporation source device of the present disclosure may include a single evaporation source and a single evaporation source shielding plate, or include at least two evaporation sources and at least two evaporation source shielding plates.

While the evaporation source device includes at least two evaporation sources and at least two evaporation source shielding plates, the driving part is further configured to control a doping ratio of a coating material in the at least two evaporation sources.

Taking two kinds of coating materials as an example, as shown in FIG. 5, the two kinds of coating materials are represented as “A” and “B”, the abscissa indicates the thickness, the ordinate indicates the doping ratio, and the two kinds of coating materials A and B are positioned in two evaporation sources, respectively. It can be seen that the evaporation source device of the present disclosure can flexibly define the doping ratio of the two materials in the thickness direction. While the prior art can only be equilibrated in the doping process, that is, the proportions of the two coating materials are approximately equal.

The evaporation source device of the present disclosure is achieved by improving a driving part in the prior art, the evaporation rate of the evaporation source is controlled by setting the rotation rate of the drive part during the coating process, to control the evaporation rate of the corresponding evaporation source. In addition, while two or more evaporation sources are co-evaporated, the doping ratio of the coating materials of the corresponding evaporation source can also be controlled.

While the present disclosure has been disclosed with reference to preferred embodiments, the above-described embodiments are not intended to limit the present disclosure, and a person having ordinary skill in the art will be able to make various changes and modifications without departing from the spirit and scope of the present disclosure, and thus the scope of the present disclosure is defined by the scope of the claims.

What is claimed is:

1. An evaporation source device configured for evaporation of a substrate, comprising:
an evaporation source disposed below the substrate;
an evaporation source shielding plate disposed between the evaporation source and the substrate; and
a driving part connected with the evaporation source shielding plate, wherein the driving part is configured to drive the evaporation source shielding plate to rotate with respect to the evaporation source, and control a rotation speed of the evaporation source shielding plate during a coating process, to adjust an evaporation rate of the evaporation source;
the driving part further configured to control a rotation cycle of the evaporation source shielding plate during the coating process, wherein the rotation cycle of the evaporation source shielding plate during the coating process is defined according to a rotation cycle of the substrate;
wherein the evaporation source device further comprises an evaporation chamber, and wherein the evaporation source, the evaporation source shielding plate, and the substrate are all located in the evaporation chamber.

2. The evaporation source device as claimed in claim 1, wherein the driving part is configured to control the rotation speed of the evaporation source shielding plate during the coating process, such that a shielding area between the evaporation source shielding plate and the evaporation source is changed, to adjust the evaporation rate of the evaporation source.

3. The evaporation source device as claimed in claim 2, wherein operation states of the evaporation source device comprise a fully closed state, a partially open state, and a fully open state.

4. The evaporation source device as claimed in claim 3, wherein while the evaporation source device is in the fully closed state, the evaporation source shielding plate fully shields the evaporation source; while the evaporation source device is in the partially open state, the evaporation source shielding plate partially shields the evaporation source; and while the evaporation source device is in the fully open state, the evaporation source shielding plate does not shield the evaporation source.

5. The evaporation source device as claimed in claim 1, further comprising a driving shaft, wherein the evaporation source shielding plate is disposed on an upper end of the driving shaft, and a lower end of the driving shaft is connected with the driving part.

6. The evaporation source device as claimed in claim 1, wherein the rotation speed of the evaporation source shielding plate during the coating process is defined according to the rotation cycle of the substrate.

7. The evaporation source device as claimed in claim 1, wherein the evaporation source device comprises at least two of the evaporation sources and at least two of the evaporation source shielding plates, each of the evaporation sources is corresponding to one of the evaporation source shielding plates; and a restriction plate is disposed between two of the evaporation sources adjacent to each other, and configured to restrict a vapor deposition area of the evaporation source.

8. The evaporation source device as claimed in claim 7, wherein the driving part is further configured to control a doping ratio of a coating material in the at least two evaporation sources.

9. An evaporation source device configured for evaporation of a substrate, comprising:
an evaporation source disposed below the substrate;
an evaporation source shielding plate disposed between the evaporation source and the substrate; and
a driving part connected with the evaporation source shielding plate, wherein the driving part is configured to drive the evaporation source shielding plate to rotate with respect to the evaporation source, and control a rotation speed of the evaporation source shielding plate during a coating process, to adjust an evaporation rate of the evaporation source.

10. The evaporation source device as claimed in claim 9, wherein the driving part is configured to control the rotation speed of the evaporation source shielding plate during the coating process, such that a shielding area between the evaporation source shielding plate and the evaporation source is changed, to adjust the evaporation rate of the evaporation source.

11. The evaporation source device as claimed in claim 10, wherein operation states of the evaporation source device comprise a fully closed state, a partial open state, and a fully open state.

12. The evaporation source device as claimed in claim 11, wherein while the evaporation source device is in the fully closed state, the evaporation source shielding plate fully shields the evaporation source; while the evaporation source device is in the partial open state, the evaporation source shielding plate partially shields the evaporation source; and while the evaporation source device is in the fully open state, the evaporation source shielding plate does not shield the evaporation source.

13. The evaporation source device as claimed in claim 9, further comprising a driving shaft, wherein the evaporation source shielding plate is disposed on an upper end of the driving shaft, and a lower end of the driving shaft is connected with the driving part.

14. The evaporation source device as claimed in claim 9, wherein the rotation speed of the evaporation source shielding plate during the coating process is defined according to the rotation cycle of the substrate.

15. The evaporation source device as claimed in claim 9, wherein the driving part is further configured to control a rotation cycle of the evaporation source shielding plate during the coating process, wherein the rotation cycle of the evaporation source shielding plate during the coating process is defined according to a rotation cycle of the substrate.

16. The evaporation source device as claimed in claim 9, wherein the evaporation source device comprises at least two of the evaporation sources and at least two of the evaporation source shielding plates, each of the evaporation sources is corresponding to one of evaporation source shielding plates; and a restriction plate is disposed between two of the evaporation sources adjacent to each other, and configured to restrict a vapor deposition area of the evaporation source.

17. The evaporation source device as claimed in claim 16, wherein the driving part is further configured to control a doping ratio of a coating material in the at least two evaporation sources.

18. The evaporation source device as claimed in claim 9, further comprising an evaporation chamber, wherein all of the evaporation source, the evaporation source shielding plate, and the substrate are located in the evaporation chamber.
